(19) United States
(12) Patent Application Publication
(10) Pub. No.: US 2026/0126817 A1
(43) Pub. Date: May 7, 2026

(54) Article Transport Facility

(71) Applicant: Daifuku Co, Ltd., Osaka-shi (JP)

(72) Inventors: Atsuhiko Mukai, Komaki-shi (JP); Makoto Kono, Komaki-shi (JP); Kazuhiro Iwamitsu, Komaki-shi (JP)

(21) Appl. No.: 19/378,621

(22) Filed: Nov. 4, 2025

(30) Foreign Application Priority Data
Nov. 5, 2024 (JP) 2024-193891

(51) Int. Cl. G05D 1/695; B61B 3/02; B61L 25/02; G05D 105/28; G05D 109/10; H01L 21/677

(52) U.S. Cl. CPC G05D 1/695; B61B 3/02; B61L 25/021; H10P 72/3216; G05D 2105/28; G05D 2109/14

(57) ABSTRACT

In an article transport facility, transport vehicles each include a speed detector that detects a current speed and a distance detector that detects an inter-vehicle distance index corresponding to a distance from another transport vehicle ahead in a travel direction. A control system performs a first target-speed determination process for determining a control target speed based on a distance-based target speed greater for a greater inter-vehicle distance index, the current speed, and the inter-vehicle distance index. The first target-speed determination process includes an acceleration determination process for determining whether to perform an acceleration process for setting the control target speed to the distance-based target speed higher than the current speed. In the acceleration determination process, the system performs the acceleration process when a relationship between the current speed and the distance-based target speed reaches a state satisfying an acceleration condition and the state continues for a determination duration or longer.

### CROSS-REFERENCE TO RELATED APPLICATION

This application claims priority to Japanese Patent Application No. 2024-193891 filed Nov. 5, 2024, the disclosure of which is hereby incorporated by reference in its entirety.

### BACKGROUND OF THE INVENTION

### Field of the Invention

The present invention relates to an article transport facility including multiple transport vehicles that travel along a travel path and transport articles, and a control system that controls the multiple transport vehicles.

### Description of Related Art

An example of such an article transport facility is described in Japanese Unexamined Patent Application Publication No. 3-6603 (hereafter referred to as JP 3-6603). The article transport facility in JP 3-6603 includes multiple transport vehicles each including a distance detector that detects a distance from a transport vehicle located ahead in a travel direction (inter-vehicle distance). The control system calculates an amount of change in the inter-vehicle distance (distance change amount) per unit time based on the inter-vehicle distance detected by the distance detector, and calculates the difference between a preset appropriate distance and the inter-vehicle distance (distance difference). The control system then increases or decreases the acceleration of each transport vehicle based on the distance change amount and the distance difference.

The article transport facility in JP 3-6603 thus causes the transport vehicles to travel while changing their accelerations to maintain appropriate inter-vehicle distances.

However, when the article transport facility in JP 3-6603 controls a transport vehicle to accelerate by increasing the acceleration in response to, for example, an increase in the inter-vehicle distance, the acceleration can be ineffective in some situations of the travel path for the transport vehicle, such as congestion in an area ahead of the transport vehicle in the travel direction. The transport vehicle may then consume extra energy. To reduce energy consumption, the acceleration frequency of the transport vehicles may be reduced. However, reducing the acceleration frequency can lower article transport efficiency of the transport vehicles.

### SUMMARY OF THE INVENTION

Article transport facilities to be developed include transport vehicles with easily reduced energy consumption and with less likelihood of lower article transport efficiency.

In response to this, an article transport facility includes a plurality of transport vehicles that travel along a travel path and transport articles, and a control system that controls the plurality of transport vehicles. Each of the plurality of transport vehicles includes a speed detector that detects a current speed that is a current travel speed of the transport vehicle, and a distance detector that detects an inter-vehicle distance index that is an index corresponding to a distance from a transport vehicle, among the plurality of transport vehicles, located ahead in a travel direction. The control system performs a first target-speed determination process for determining, based on a distance-based target speed, the current speed, and the inter-vehicle distance index, a control target speed that is a target value in controlling the travel speed. The distance-based target speed is a target value for the travel speed and is preset to be greater for a greater inter-vehicle distance index. The first target-speed determination process includes an acceleration determination process for determining whether to perform an acceleration process for setting the control target speed to the distance-based target speed higher than the current speed. In the acceleration determination process, the control system determines to perform the acceleration process in response to a relationship between the current speed and the distance-based target speed reaching an accelerable state satisfying a preset acceleration condition and the accelerable state continuing for a preset determination duration or longer.

In this structure, the acceleration process is not performed unless the accelerable state continues for the preset determination duration or longer in the acceleration determination process after the relationship between the current speed and the distance-based target speed reaches the accelerable state satisfying the preset acceleration condition. This reduces ineffective acceleration of the transport vehicles and allows the transport vehicles to travel efficiently. The structure can thus include transport vehicles with easily reduced energy consumption and with less likelihood of lower article transport efficiency.

### BRIEF DESCRIPTION OF THE DRAWINGS

FIG. 1 is a schematic diagram of an article transport facility according to an embodiment, showing its entire structure.

FIG. 2 is a side view of transport vehicles included in the article transport facility according to the embodiment.

FIG. 3 is a block diagram of the article transport facility according to the embodiment.

FIG. 4 is a flowchart of an example control process performed by a control system.

FIG. 5 is a diagram showing inter-vehicle distance indexes in another embodiment.

FIG. 6 is a diagram showing inter-vehicle distance indexes in another embodiment.

### DESCRIPTION OF THE INVENTION

An article transport facility 100 according to an embodiment will be described below with reference to the drawings.

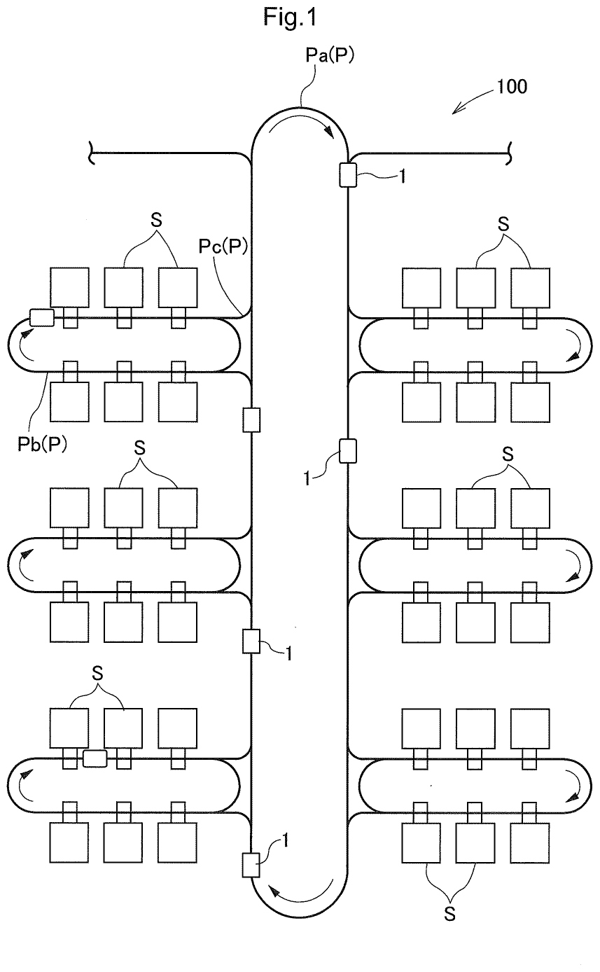

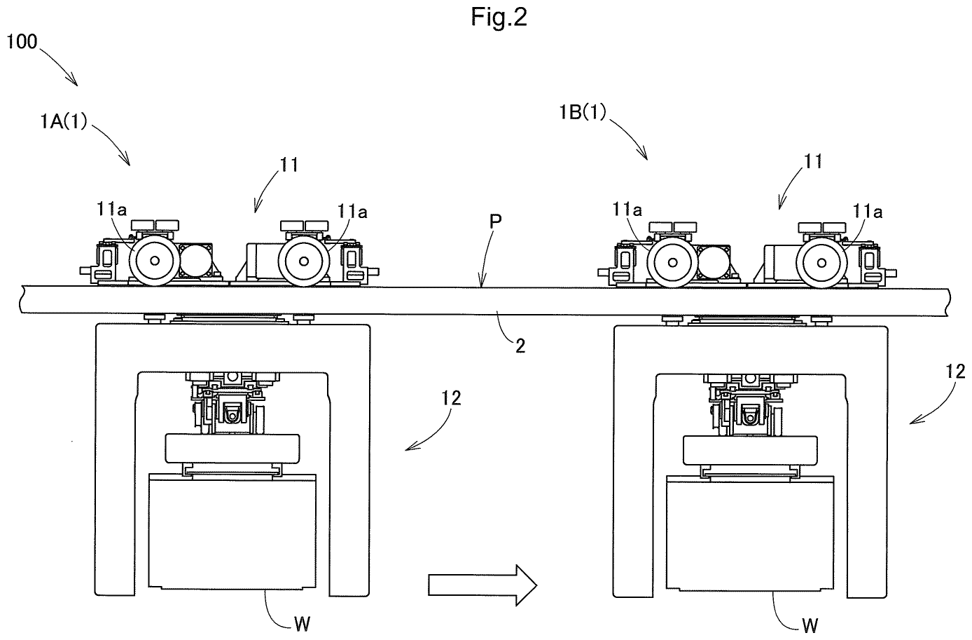

As shown in FIG. 1, the article transport facility 100 includes multiple transport vehicles 1 that travel along a travel path P and transport articles W (refer to FIG. 2).

In the present embodiment, the travel path P includes a looped main path Pa, multiple looped subpaths Pb each extending through multiple stations S, and multiple connection paths Pc that connect the main path Pa and the multiple subpaths Pb.

At each station S, for example, an article W is transferred between the station S and a transport vehicle 1 stopping at a position corresponding to the station S. At each station S, articles W are transferred to, for example, a load port of a processing device for processing the articles W, a load-unload port of a storage device for storing the articles W, or a storage shelf for temporarily storing the articles W.

As shown in FIG. 2, the article transport facility 100 according to the present embodiment further includes a traveling rail 2 hung from and supported by the ceiling. The traveling rail 2 is disposed along the travel path P. In the present embodiment, each transport vehicle 1 is a ceiling-hung transport vehicle guided along the traveling rail 2 and travels along the travel path P. The articles W are, for example, front opening unified pods (FOUPs) holding semiconductor substrates or glass substrates to be used as a material for displays.

Each transport vehicle 1 according to the present embodiment includes a traveler 11 and a transferer 12.

The traveler 11 includes travel wheels 11a that roll on the traveling rail 2. In the present embodiment, at least one of the multiple travel wheels 11a is rotated by a driving force of a travel motor (not shown) to roll on the traveling rail 2, thus causing the traveler 11 to travel along the travel path P.

The transferer 12 transfers articles W to and from the stations S. Although not described in detail, the transferer 12 includes, for example, a holder that holds an article W, and a lifter that lifts and lowers the holder with respect to the traveler 11. The transferer 12 also includes, as appropriate, a horizontal mover that horizontally moves the holder with respect to the traveler 11, and a rotator that rotates the holder about a rotation axis extending in the vertical direction with respect to the traveler 11. The transferer 12 may include any component, other than those described above, to transfer articles W to and from the stations S.

In the example described below, any transport vehicle 1 is referred to as a target vehicle 1A, and another transport vehicle 1 located ahead of the target vehicle 1A in a travel direction (refer to a solid white arrow in FIG. 2) is referred to as a preceding vehicle 1B.

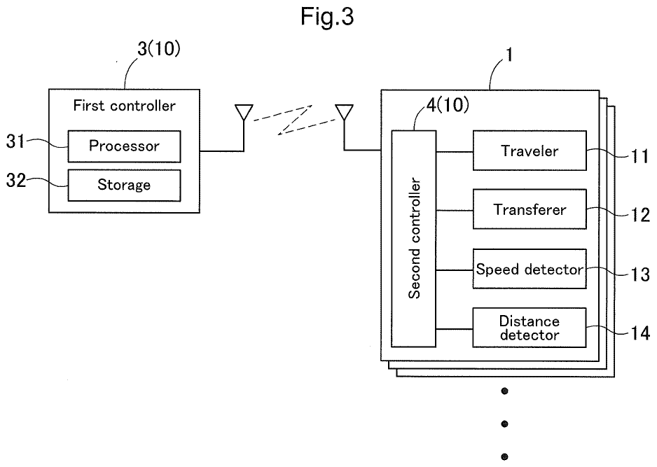

As shown in FIG. 3, the article transport facility 100 includes a control system 10 that controls the multiple transport vehicles 1. In the present embodiment, the control system 10 includes a first controller 3 disposed at a predetermined location in the article transport facility 100, and second controllers 4 included in each of the multiple transport vehicles 1. The first controller 3 and each of the multiple second controllers 4 wirelessly communicate with each other.

The first controller 3 outputs control commands to the multiple second controllers 4. The first controller 3 includes a processor 31 that performs a predefined process, and a storage 32 that stores various information items.

The second controllers 4 each control the operation of the corresponding traveler 11 and the corresponding transferer 12 based on the control command from the first controller 3.

Each of the multiple transport vehicles 1 includes a speed detector 13 that detects a current speed V that is the current travel speed of the transport vehicle (target vehicle 1A), and a distance detector 14 that detects an inter-vehicle distance index D that is an index corresponding to the distance from another transport vehicle 1 located ahead in the travel direction (preceding vehicle 1B). In the present embodiment, the inter-vehicle distance index D indicates the distance between the target vehicle 1A and the preceding vehicle 1B.

In the present embodiment, the second controllers 4 each transmit, to the first controller 3, the current speed V detected by the corresponding speed detector 13 and the inter-vehicle distance index D detected by the corresponding distance detector 14.

The control system 10 performs a first target-speed determination process based on the current speed V, the inter-vehicle distance index D, and a distance-based target speed V1 for determining a control target speed V2 that is a target value in controlling the travel speed of each transport vehicle 1. In the present embodiment, the control system 10 further performs a second target-speed determination process for determining the control target speed V2. In the present embodiment, the processor 31 in the first controller 3 performs control processes for the transport vehicles 1, including the first target-speed determination process and the second target-speed determination process.

The distance-based target speed V1 is a target value for the travel speed of each transport vehicle 1. The distance-based target speed V1 is preset and is higher for a greater inter-vehicle distance index D. In the present embodiment, the storage 32 in the first controller 3 stores a target speed table including the distance-based target speed V1 for each inter-vehicle distance index D. The processor 31 in the first controller 3 refers to the target speed table stored in the storage 32 to obtain the distance-based target speed V1 corresponding to the inter-vehicle distance index D detected by the distance detector 14.

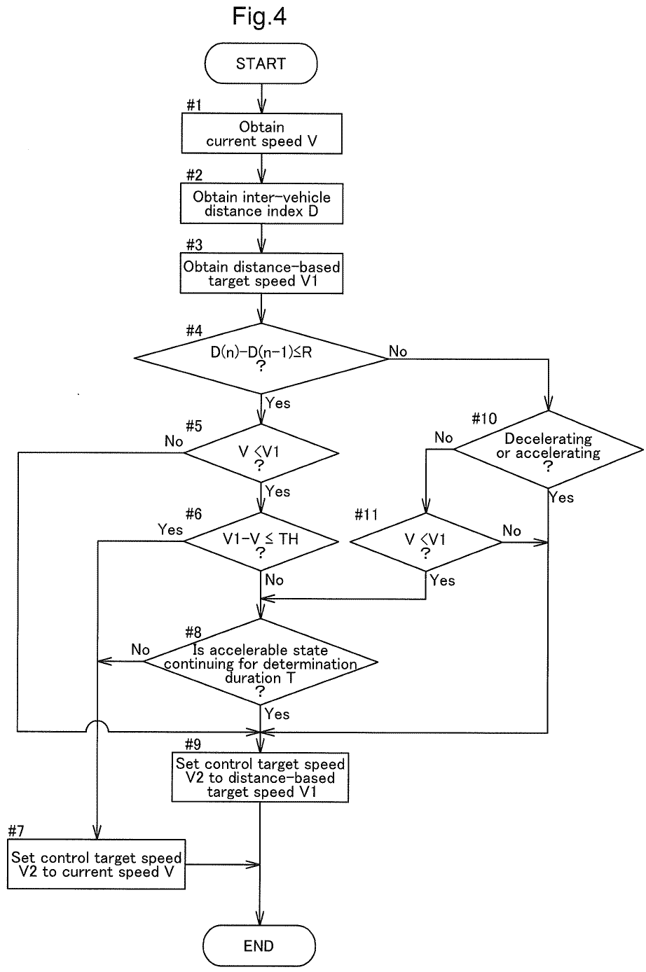

Hereafter, the control process performed by the control system 10 is described with reference to FIG. 4. FIG. 4 is a flowchart of an example control process performed by the control system 10.

The control system 10 performs the control process described below at predefined time intervals.

As shown in FIG. 4, the control system 10 first causes the speed detector 13 to detect the current speed V and obtains the detected current speed V (step #1). The control system 10 then causes the distance detector 14 to detect the inter-vehicle distance index D and obtains the detected inter-vehicle distance index D (step #2). The control system 10 then obtains the distance-based target speed V1 corresponding to the inter-vehicle distance index D (step #3).

The current speed V may or may not be obtained (step #1) before the inter-vehicle distance index D is detected (step #2) or the distance-based target speed V1 (step #3) is obtained, and may be obtained in parallel with or after the inter-vehicle distance index D is detected and the distance-based target speed V1 is obtained (steps #2 and #3).

Subsequently, the control system 10 determines whether an increase in the inter-vehicle distance index D per predefined time (D(n)−D(n−1)) is less than or equal to a preset reference value R (step #4). D(n) indicates the current inter-vehicle distance index D, and D(n−1) indicates an inter-vehicle distance index D detected last time. When D(n) is less than D(n−1), the increase in the inter-vehicle distance index D per predefined time is a negative value. In the present embodiment, the inter-vehicle distance index D is the distance between a transport vehicle 1 and another transport vehicle 1 located ahead of the transport vehicle 1 in the travel direction as described above. Thus, in the present embodiment, the reference value R indicates a distance (e.g., 200 mm). The reference value R may be used as a correction value, and may be set to zero or a negative value instead of a positive value.

When the increase in the inter-vehicle distance index D per predefined time (D(n)−D(n−1)) is less than or equal to the reference value R (Yes in step #4), the control system 10 performs the first target-speed determination process. For example, when the inter-vehicle distance between the target vehicle 1A and the preceding vehicle 1B remains substantially unchanged or decreases in the predefined time, the control system 10 determines the result to be affirmative in step #4. When the inter-vehicle distance between the target vehicle 1A and the preceding vehicle 1B substantially increases in the predefined time, the control system 10 determines the result to be negative in step #4.

In the first target-speed determination process, the control system 10 first determines whether the current speed V is lower than the distance-based target speed V1 (step #5).

When the current speed V is lower than the distance-based target speed V1 (Yes in step #5), the control system 10 determines whether the difference between the current speed V and the distance-based target speed V1 is less than or equal to a preset determination threshold TH (step #6).

The difference between the current speed V and the distance-based target speed V1 is, for example, a value simply obtained by subtracting the current speed V from the distance-based target speed V1. The determination threshold TH indicates a value of speed (e.g., 10 m/min). In some embodiments, speed ranges of multiple levels may be defined using numerical values each corresponding to the travel speed of the transport vehicles 1, and the value obtained by subtracting a speed range including the current speed V from a speed range including the distance-based target speed V1 (the value indicating the difference between the levels of the speed ranges) may be used as the difference between the current speed V and the distance-based target speed V1. In this case, the determination threshold TH is a value indicating a speed range (a value indicating a level of a speed range, for example, 1).

When the difference between the current speed V and the distance-based target speed V1 is less than or equal to the determination threshold TH (Yes in step #6), the control system 10 performs a speed maintaining process for setting the control target speed V2 to the current speed V (step #7).

When the difference between the current speed V and the distance-based target speed V1 is greater than the determination threshold TH (No in step #6), the control system 10 determines whether an accelerable state continues for a preset determination duration T or longer (step #8).

The accelerable state is a state in which the relationship between the current speed V and the distance-based target speed V1 satisfies a preset acceleration condition. In the present embodiment, when the increase in the inter-vehicle distance index D per predefined time (D(n)−D(n−1)) is less than or equal to the reference value R (Yes in step #4), the acceleration condition is a condition in which the current speed V is lower than the distance-based target speed V1 (Yes in step #5) by a difference greater than the determination threshold TH (No in step #6).

In the present embodiment, the determination duration T indicates a value corresponding to the number of times the control system 10 has performed the control process (e.g., the time corresponding to 10 times the duration for the control system 10 to perform the control process). For example, the number of times the distance detector 14 has detected the inter-vehicle distance index D may be herein the number of times the control process is performed. In this case, the duration for one cycle for the distance detector 14 to detect the inter-vehicle distance index D corresponds to the duration for one control process.

When the accelerable state continues for the determination duration T or longer (Yes in step #8), the control system 10 sets the control target speed V2 to the distance-based target speed V1 (step #9). In this case, the distance-based target speed V1 is higher than the current speed V (Yes in step #5). Thus, an acceleration process is performed.

In step #5, when the current speed V is higher than or equal to the distance-based target speed V1 (No in step #5), the control system 10 also sets the control target speed V2 to the distance-based target speed V1 (step #9). When the distance-based target speed V1 is lower than the current speed V, a deceleration process is performed. When the distance-based target speed V1 is equal to the current speed V, the speed maintaining process is performed.

When the accelerable state continues for less than the determination duration T (No in step #8), the control system 10 performs the speed maintaining process to set the control target speed V2 to the current speed V (step #7).

In step #4, when the increase in the inter-vehicle distance index D per predefined time (D(n)−D(n−1)) is greater than the reference value R (No in step #4), the control system 10 performs the second target-speed determination process.

In the second target-speed determination process, the control system 10 first determines whether the control target speed V2 set in the previous control process is the distance-based target speed V1, or more specifically, determines whether the previous control process has involved the deceleration process or the acceleration process (step #10).

When the deceleration process or the acceleration process is performed in the previous control process (Yes in step #10), the control system 10 performs the deceleration process or the acceleration process, or more specifically, maintains the control target speed V2 at the distance-based target speed V1 (step #9).

When no deceleration or acceleration process is performed in the previous control process, or more specifically, when the speed maintaining process has been performed in the previous control process (No in step #10), the control system 10 determines whether the current speed V is lower than the distance-based target speed V1 (step #11).

When the current speed V is lower than the distance-based target speed V1 (Yes in step #11), the control system 10 determines whether the accelerable state satisfying the acceleration condition continues for the determination duration T or longer (step #8). In the present embodiment, when the increase in the inter-vehicle distance index D per predefined time (D(n)−D(n−1)) is greater than the reference value R (No in step #4), the acceleration condition is a condition in which the current speed V is lower than the distance-based target speed V1 (Yes in step #11).

When the accelerable state continues for the determination duration T or longer (Yes in step #8), the control system 10 sets the control target speed V2 to the distance-based target speed V1 (step #9). In this case, the distance-based target speed V1 is higher than the current speed V (Yes in step #11), and the acceleration process is thus performed.

When the accelerable state continues for less than the determination duration T (No in step #8), the control system 10 performs the speed maintaining process for setting the control target speed V2 to the current speed V (step #7).

In step #11, when the current speed V is higher than or equal to the distance-based target speed V1 (No in step #11), the control system 10 sets the control target speed V2 to the distance-based target speed V1 (step #9). When the distance-based target speed V1 is lower than the current speed V, the deceleration process is performed. When the distance-based target speed V1 is equal to the current speed V, the speed maintaining process is performed.

As described above, the first target-speed determination process includes an acceleration determination process (corresponding to steps #5, #6, and #8) for determining whether to perform the acceleration process (corresponding to step #9) for setting the control target speed V2 to the distance-based target speed V1 higher than the current speed V.

In the acceleration determination process (corresponding to steps #5, #6, and #8), the control system 10 determines to perform the acceleration process (corresponding to step #9) in response to the relationship between the current speed V and the distance-based target speed V1 reaching the accelerable state satisfying the preset acceleration condition (corresponding to steps #5 and #6) and the accelerable state continuing for the preset determination duration T or longer (corresponding to Yes in step #8).

As described above, the acceleration process (corresponding to step #9) is not performed unless the accelerable state continuing for the preset determination duration T or longer (corresponding to Yes in step #8) in the acceleration determination process (corresponding to steps #5, #6, and #8) after the relationship between the current speed V and the distance-based target speed V1 reaches the accelerable state (corresponding to steps #5 and #6) satisfying the preset acceleration condition. This reduces ineffective acceleration of the transport vehicles 1 and allows the transport vehicles 1 to travel efficiently. The structure can thus include transport vehicles 1 with easily reduced energy consumption and with less likelihood of lower transport efficiency for the articles W.

Congestion with the transport vehicles 1 is likely to occur at junctions and intersections of the travel path P (e.g., at the points connecting the main path Pa and the connection paths Pc in FIG. 1), and the transport vehicles 1 are likely to consume more energy at the junctions and the intersections. Thus, the above control process can more effectively reduce energy consumption for the travel path P including many junctions and intersections.

In the present embodiment, the acceleration determination process (corresponding to steps #5, #6, and #8) includes determining (corresponding to step #8) whether to perform the speed maintaining process for setting the control target speed V2 to the current speed V (corresponding to step #7). In the acceleration determination process (corresponding to steps #5, #6, and #8), the control system 10 determines, in response to the accelerable state continuing for less than the determination duration T (corresponding to No in step #8), to perform the speed maintaining process (corresponding to step #7) without performing the acceleration process (corresponding to step #9).

In the present embodiment, in response to the increase in the inter-vehicle distance index D per predefined time (D(n)−D(n−1)) being less than or equal to the reference value R (corresponding to Yes in step #4), the control system 10 performs the acceleration determination process (corresponding to steps #5, #6, and #8) with the acceleration condition in which the current speed V is lower than the distance-based target speed V1 (corresponding to Yes in step #5) by a difference greater than the determination threshold TH (corresponding to No in step #6).

In the acceleration determination process (corresponding to steps #5, #6, and #8) in the present embodiment, the control system 10 determines to perform, in response to the current speed V being lower than the distance-based target speed V1 (corresponding to Yes in step #5) by a difference less than or equal to the determination threshold TH (corresponding to Yes in step #6), the speed maintaining process (corresponding to step #7) without performing the acceleration process (corresponding to step #9).

In the present embodiment, the first target-speed determination process further includes a deceleration determination process (corresponding to step #5) for determining whether to perform the deceleration process (corresponding to step #9) for setting the control target speed V2 to the distance-based target speed V1 lower than the current speed V.

In the deceleration determination process (corresponding to step #5), the control system 10 determines to perform the deceleration process (corresponding to step #9) in response to the relationship between the current speed V and the distance-based target speed V1 satisfying a preset deceleration condition (corresponding to No in step #5).

In the present embodiment, the control system 10 further performs the second target-speed determination process (corresponding to steps #10 and #11) for determining the control target speed V2 in response to the increase in the inter-vehicle distance index D per predefined time (D(n)−D(n−1)) being greater than the reference value R (corresponding to No in step #4).

In the present embodiment, the control system 10 in the second target-speed determination process (corresponding to steps #10 and #11) maintains, for the control target speed V2 being the distance-based target speed V1 (corresponding to Yes in step #10), the control target speed V2 at the distance-based target speed V1.

In response to the current speed V being higher than the distance-based target speed V1 (corresponding to No in step #11) during the speed maintaining process (corresponding to step #7 and No in step #10), the control system 10 determines to perform the deceleration process (corresponding to step #9).

In response to the current speed V being lower than the distance-based target speed V1 (corresponding to Yes in step #11) during the speed maintaining process (corresponding to step #7 and No in step #10), the control system 10 performs the acceleration determination process (corresponding to steps #8 and #11) with the acceleration condition in which the current speed V is lower than the distance-based target speed V1 (corresponding to Yes in step #11).

### Other Embodiments

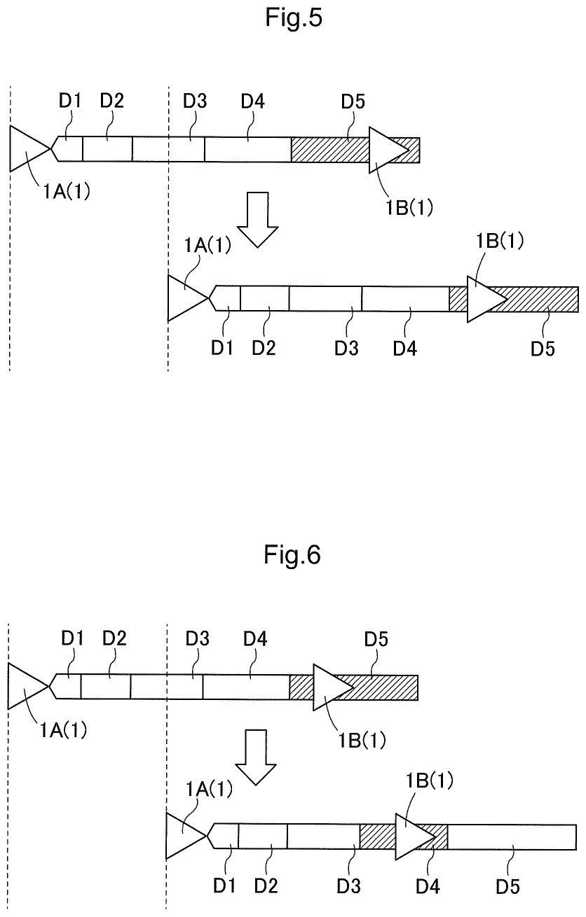

(1) In the above embodiment, the inter-vehicle distance index D is an inter-vehicle distance between the target vehicle 1A and the preceding vehicle 1B. In some embodiments, for example, multiple distance ranges may be defined using numerical values each corresponding to inter-vehicle distances between the target vehicle 1A and the preceding vehicle 1B as shown in FIGS. 5 and 6, and a numerical value indicating the distance range including the inter-vehicle distance between the target vehicle 1A and the preceding vehicle 1B may be used as the inter-vehicle distance index D. In the example shown in FIGS. 5 and 6, five distance ranges of a first range D1 to a fifth range D5 are set in ascending numerical order. The first range D1 to the fifth range D5 are defined with numerical values 1 to 5. In the present embodiment, the reference value R is thus a value indicating a distance range (e.g., 0). In the present example, the first range D1 to the fifth range D5 are gradually wider from the first range D1 to the fifth range D5.

In the example shown in FIG. 5, the inter-vehicle distance between the target vehicle 1A and the preceding vehicle 1B in the fifth range D5 has decreased after elapse of a predefined time, but the distance range including the inter-vehicle distance remains unchanged from the fifth range D5. In this case, the increase in the inter-vehicle distance index D per predefined time (D(n)−D(n−1)) is 0. In FIG. 5, the distance range including the inter-vehicle distance between the target vehicle 1A and the preceding vehicle 1B is hatched. The same applies to FIG. 6.

In the example shown in FIG. 6, the inter-vehicle distance between the target vehicle 1A and the preceding vehicle 1B in the fifth range D5 has decreased after elapse of a predefined time, and the distance range including the inter-vehicle distance changes from the fifth range D5 to the fourth range D4. In this state, the increase in the inter-vehicle distance index D per predefined time (D(n)−D(n−1)) is −1.

(2) In the above embodiment, each transport vehicle 1 is a ceiling-hung transport vehicle guided along the traveling rail 2 hung from the ceiling and travels along the travel path P. In some embodiments, for example, the transport vehicle 1 may be a tracked transport vehicle that travels along rails on the floor surface. The transport vehicle 1 may also be a trackless transport vehicle such as an automated guided vehicle (AGV) or an autonomous mobile robot (AMR). The transport vehicle 1 that is a trackless transport vehicle travels along a virtual travel path P, rather than a physical travel path P including rails or other members. The travel path P can be defined by multiple detectable members, such as two-dimensional codes and radio frequency (RF) tags, installed on the floor surface. The travel path P may also be virtually defined, without such detectable members on the floor surface, based on a route calculated using recognition results of the surrounding environment.

(3) In the above embodiment, the control system 10 includes the first controller 3 and the second controllers 4 each included in the corresponding one of the multiple transport vehicles 1. The first controller 3 provides instructions to the multiple second controllers 4. In some embodiments, for example, the multiple second controllers 4 may operate independently of or in cooperation with one another.

(4) In the above embodiment, the determination duration T corresponds to the number of times the control system 10 has performed the control process (e.g., the duration corresponding to 10 times the duration for the control system 10 to perform one control process). In some embodiments, the determination duration T may be set independently of the number of times the control process is performed by the control system 10.

(5) The structure described in each of the above embodiments may be combined with any other structures described in the other embodiments unless any contradiction arises. For other structures as well, the embodiments described herein are merely illustrative in all aspects. Thus, the embodiments described herein may be modified variously as appropriate without departing from the spirit and scope of the disclosure.

### Overview of Present Embodiment

An overview of the article transport facility described above is briefly provided below.

An article transport facility includes a plurality of transport vehicles that travel along a travel path and transport articles, and a control system that controls the plurality of transport vehicles. Each of the plurality of transport vehicles includes a speed detector that detects a current speed that is a current travel speed of the transport vehicle, and a distance detector that detects an inter-vehicle distance index that is an index corresponding to a distance from a transport vehicle, among the plurality of transport vehicles, located ahead in a travel direction. The control system performs a first target-speed determination process for determining, based on a distance-based target speed, the current speed, and the inter-vehicle distance index, a control target speed that is a target value in controlling the travel speed. The distance-based target speed is a target value for the travel speed and is preset to be greater for a greater inter-vehicle distance index. The first target-speed determination process includes an acceleration determination process for determining whether to perform an acceleration process for setting the control target speed to the distance-based target speed higher than the current speed. In the acceleration determination process, the control system determines to perform the acceleration process in response to a relationship between the current speed and the distance-based target speed reaching an accelerable state satisfying a preset acceleration condition and the accelerable state continuing for a preset determination duration or longer.

In this structure, the acceleration process is not performed unless the accelerable state continues for the preset determination duration or longer in the acceleration determination process after the relationship between the current speed and the distance-based target speed reaches the accelerable state satisfying the preset acceleration condition. This reduces ineffective acceleration of the transport vehicles and allows the transport vehicles to travel efficiently. The structure can thus include transport vehicles with easily reduced energy consumption and with less likelihood of lower article transport efficiency.

The acceleration determination process may include determining whether to perform a speed maintaining process for setting the control target speed to the current speed. In the acceleration determination process, the control system may determine, in response to the accelerable state continuing for less than the determination duration, to perform the speed maintaining process without performing the acceleration process.

In this structure, the speed maintaining process is performed instead of the acceleration process unless the accelerable state continues for the determination duration or longer after the relationship between the current speed and the distance-based target speed reaches the accelerable state satisfying the acceleration condition. This easily reduces ineffective acceleration of the transport vehicles. The transport vehicles are thus likely to consume less energy.

In the structure described above, in response to an increase in the inter-vehicle distance index per predefined time being less than or equal to a preset reference value, the control system may perform the acceleration determination process with the acceleration condition in which the current speed is lower than the distance-based target speed by a difference greater than a preset determination threshold.

In this structure, when the increase in the inter-vehicle distance index per predefined time is zero or a negative value or when the increase is a relatively small positive value, the acceleration process is not performed with the current speed being lower than the distance-based target speed by a difference that is relatively small. This easily reduces ineffective acceleration of the transport vehicles. The transport vehicles are thus likely to consume less energy.

In the structure described above, in the acceleration determination process, the control system may determine to perform, in response to the current speed being lower than the distance-based target speed by a difference less than or equal to the determination threshold, the speed maintaining process without performing the acceleration process.

In this structure, when the increase in the inter-vehicle distance index per predefined time is zero or a negative value or when the increase is a relatively small positive value, the speed maintaining process is performed instead of the acceleration process with the current speed being lower than the distance-based target speed by a difference that is relatively small. This easily reduces ineffective acceleration of the transport vehicles. The transport vehicles are thus likely to consume less energy.

The first target-speed determination process may further include a deceleration determination process for determining whether to perform a deceleration process for setting the control target speed to the distance-based target speed lower than the current speed. In the deceleration determination process, the control system may determine to perform the deceleration process in response to a relationship between the current speed and the distance-based target speed satisfying a preset deceleration condition.

In this structure, the deceleration process can be appropriately performed.

In the structure described above, the control system may further perform a second target-speed determination process for determining the control target speed in response to the increase in the inter-vehicle distance index per predefined time being greater than the reference value. In the second target-speed determination process, for the control target speed being the distance-based target speed, the control system may maintain the control target speed at the distance-based target speed. In response to the current speed being higher than the distance-based target speed during the speed maintaining process, the control system may determine to perform the deceleration process. In response to the current speed being lower than the distance-based target speed during the speed maintaining process, the control system may perform the acceleration determination process with the acceleration condition in which the current speed is lower than the distance-based target speed.

In this structure, the second target-speed determination process is performed when the increase in the inter-vehicle distance index per predefined time is relatively large. In the second target-speed determination process, when the process being performed is the deceleration process or the acceleration process, the deceleration process or the acceleration process is maintained. In the second target-speed determination process, when the current speed is higher than the distance-based target speed during the speed maintaining process, the deceleration process is performed. When the current speed is lower than the distance-based target speed during the speed maintaining process, the acceleration determination process is performed without including the condition in which the difference between the current speed and the distance-based target speed is greater than the determination threshold into the acceleration condition. Thus, when the increase in the inter-vehicle distance index per predefined time is relatively large, this structure can cause the transport vehicles to travel efficiently without overly reducing the frequency of accelerating the transport vehicles.

### INDUSTRIAL APPLICABILITY

The technique according to one or more embodiments of the disclosure can be used for an article transport facility including multiple transport vehicles that travel along a travel path and transport articles, and a control system that controls the multiple transport vehicles.

What is claimed is:

1. An article transport facility, comprising:
a plurality of transport vehicles configured to travel along a travel path and transport articles; and
a control system configured to control the plurality of transport vehicles,
each of the plurality of transport vehicles comprising:
a speed detector configured to detect a current speed that is a current travel speed of the transport vehicle, and
a distance detector configured to detect an inter-vehicle distance index that is an index corresponding to a distance from a transport vehicle, among the plurality of transport vehicles, located ahead in a travel direction,
wherein the control system is configured to perform a first target-speed determination process for determining, based on a distance-based target speed, the current speed, and the inter-vehicle distance index, a control target speed that is a target value in controlling the travel speed, where the distance-based target speed is a target value for the travel speed and is preset to be greater for a greater inter-vehicle distance index,
wherein the first target-speed determination process comprises an acceleration determination process for determining whether to perform an acceleration process for setting the control target speed to the distance-based target speed higher than the current speed, and
wherein in the acceleration determination process, the control system is configured to determine to perform the acceleration process in response to a relationship between the current speed and the distance-based target speed reaching an accelerable state satisfying a preset acceleration condition and the accelerable state continuing for a preset determination duration or longer.

2. The article transport facility according to claim 1, wherein:
the acceleration determination process comprises determining whether to perform a speed maintaining process for setting the control target speed to the current speed, and
in the acceleration determination process, the control system determines, in response to the accelerable state continuing for less than the determination duration, to perform the speed maintaining process without performing the acceleration process.

3. The article transport facility according to claim 2, wherein:
in response to an increase in the inter-vehicle distance index per predefined time being less than or equal to a preset reference value, the control system performs the acceleration determination process with the acceleration condition in which the current speed is lower than the distance-based target speed by a difference greater than a preset determination threshold.

4. The article transport facility according to claim 3, wherein:
in the acceleration determination process, the control system determines to perform, in response to the current speed being lower than the distance-based target speed by a difference less than or equal to the determination threshold, the speed maintaining process without performing the acceleration process.

5. The article transport facility according to claim 3, wherein:
the first target-speed determination process further comprises a deceleration determination process for determining whether to perform a deceleration process for setting the control target speed to the distance-based target speed lower than the current speed, and
in the deceleration determination process, the control system determines to perform the deceleration process in response to a relationship between the current speed and the distance-based target speed satisfying a preset deceleration condition.

6. The article transport facility according to claim 5, wherein:
the control system further performs a second target-speed determination process for determining the control target speed in response to the increase in the inter-vehicle distance index per predefined time being greater than the reference value, and
in the second target-speed determination process:
for the control target speed being the distance-based target speed, the control system maintains the control target speed at the distance-based target speed,
in response to the current speed being higher than the distance-based target speed during the speed maintaining process, the control system determines to perform the deceleration process, and
in response to the current speed being lower than the distance-based target speed during the speed maintaining process, the control system performs the acceleration determination process with the acceleration condition in which the current speed is lower than the distance-based target speed.

7. The article transport facility according to claim 4, wherein:
the first target-speed determination process further comprises a deceleration determination process for determining whether to perform a deceleration process for setting the control target speed to the distance-based target speed lower than the current speed, and
in the deceleration determination process, the control system determines to perform the deceleration process in response to a relationship between the current speed and the distance-based target speed satisfying a preset deceleration condition.

8. The article transport facility according to claim 7, wherein:
the control system further performs a second target-speed determination process for determining the control target speed in response to the increase in the inter-vehicle distance index per predefined time being greater than the reference value, and
in the second target-speed determination process:
for the control target speed being the distance-based target speed, the control system maintains the control target speed at the distance-based target speed,
in response to the current speed being higher than the distance-based target speed during the speed maintaining process, the control system determines to perform the deceleration process, and
in response to the current speed being lower than the distance-based target speed during the speed maintaining process, the control system performs the acceleration determination process with the acceleration condition in which the current speed is lower than the distance-based target speed.
